(19) United States
(12) Patent Application Publication
(10) Pub. No.: US 2022/0028671 A1
(43) Pub. Date: Jan. 27, 2022

(54) Device and method for plasma treatment of containers

(71) Applicant: KHS Corpoplast GmbH, Hamburg (DE)

(72) Inventors: Michael HERBORT, Hamburg (DE); Björn BEYERSDORFF, Wedel (DE)

(73) Assignee: KHS Corpoplast GmbH, Hamburg (DE)

(21) Appl. No.: 17/296,265

(22) PCT Filed: Nov. 22, 2019
(86) PCT No.: PCT/EP2019/082169

§ 371 Date: May 24, 2021

(51) Int. Cl. H01J 37/32

(52) U.S. Cl. CPC H01J 37/32981; H01J 37/32394; H01J 2237/332; H01J 37/32816; H01J 37/32449

(57) ABSTRACT

A device for the plasma treatment of containers comprises a process gas producer for producing a process gas mixture and at least one coating station, which comprises at least one plasma chamber having a treatment place, in which plasma chamber at least one container having a container interior can be inserted and positioned on the treatment place, each plasma chamber being at least partially evacuable in order to suck the process gas provided by the process gas producer through the container, the interior thereof thus being provided with an inner coating by means of plasma treatment, and pressure-measuring apparatuses being provided at predefined points of the device in order to ensure the process stability. The pressure-measuring apparatuses at least at some of the predefined points of the device comprise gas-type-dependent pressure transducers.

### CROSS-REFERENCE TO RELATED APPLICATION

This application is a national stage application, filed under 35 U.S.C. § 371, of International Patent Application No. PCT/EP2019/082169, filed on Nov. 22, 2019, which claims the benefit of German Patent Application No. 102018129694.0, filed Nov. 26, 2018.

### TECHNICAL FIELD

The disclosure relates to a device for plasma treatment of containers and to a method for plasma treatment of containers.

### BACKGROUND

A device and a method for plasma treatment of containers are generally known, for example, from WO 2017/102280 A2. The process gas generator of WO 2017/102280 A2 mixes the process gas mixtures of O2, Ar, HMDSO (hexamethyldisiloxane) and HMDSN (hexamethyldisilazane). Mass flow controllers dose the provided process gas from the gas phase and the vacuum of the vacuum system sucks the provided process gas through the coating stations. In the coating stations, the process gas is reacted to create a barrier layer in the bottles. Several parameters determine the pressure conditions in the system: Gas flow, pumping speed of the vacuum pumps and conductance values of the pipelines (depending on pipe length and cross-section). If the above parameters are known with sufficient accuracy, the pressure ratios at any point in the system can be calculated. In general, the highest absolute pressure is in the gas generator, the lowest is the suction pressure directly at the inlet of the vacuum pump(s).

For each type of bottle to be coated, a special recipe is created defining, among other things, the process gas mixture of O2, Ar, HMDSO and HMDSN. This mixture is not changed during the operation of the machine (with the selected recipe). Since the relevant pipelines also do not change significantly, very stable pressure conditions result during coating operation or in the standby phases when no bottles are currently being coated in the device. The device is only released for coating when a stable condition is reached in the vacuum system. Due to the described stability of the system (pressure gradient), the pressure values to be expected for a given recipe can be calculated and measured in the normal state. For a set process gas mixture, a characteristic pressure gradient results, since the pipe conductance values and the pumping speed of the device practically do not change. However, the absolute pressure in the gas generator may depend on the operating condition of the device. The absolute pressure of the process gas mixture in the process gas generator is measured with gas-type-independent pressure transducers. For process control, it is evaluated whether the measured pressure is within a specified range.

In a gas-type-independent pressure transducer, a so-called diaphragm vacuum gauge, for example, the pressure p acts on a diaphragm with a defined area A and deflects the diaphragm in proportion to the pressure. A sensor measures the deflection. In the simplest case, for example, a mechanism transmits the deflection to a pointer that moves over a pressure scale. Piezoresistive or capacitive sensors pick up the pressure signal and convert it into an electrical signal.

The disadvantage of the gas-type-independent pressure transducers that have been used exclusively up to now is that they cannot detect gas compositions, which is why process control is carried out without taking the gas composition into account. Another disadvantage is that gas-type-independent pressure transducers are relatively expensive, which makes their use uneconomical at all relevant measuring locations of the plasma treatment device, and that those pressure transducers may require the approval of the German Federal Office of Economics and Export Control (BAFA).

### SUMMARY

One object of the present disclosure is to provide a device and a method for plasma treatment of containers, which ensures improved process control with increased economic efficiency.

This object is solved for the generic device and for the generic method by the characterizing features of the respective independent claim. The dependent claims mention advantageous embodiments of the device according to the invention. Accordingly, the invention provides that the pressure measuring devices comprise gas-type-dependent pressure transducers at least at a part of the predetermined locations of the device. The use of the gas-type-dependent pressure measurement achieves that it is possible to draw conclusions on properties of the respective gas from the determined pressure value, for example on the state of a gas mixture, i.e. its constancy or variation. Such statements cannot be made with a gas-type-independent pressure measurement.

The Pirani thermal conductivity vacuum gauge (Pirani gauge tube or load cell) uses pressure transducers based on the principle that, the thermal conductivity of gases is pressure-dependent within certain limits, to measure pressure. Pirani load cells have a gas type dependence due to the calorimetric measuring principle, in which the heat loss of a heated wire, the heat loss being induced by the residual gas is measured. For this reason, the Pirani load cell can advantageously be used as a gas-type-dependent pressure transducer.

Advantageously, in the case of several coating stations, a change in the process gas mixture in a respective plasma chamber can be concluded by evaluating the measured pressure values that can be measured in the plasma chambers with gas-type-dependent pressure transducers. A change in the process gas mixture can have a global cause, for example due to contaminated process starting materials, malfunction of the gas supply (flow control of the starting materials) or leakages in the gas generator. Local causes are also possible, especially caused by leakage into the vacuum system. Furthermore, by evaluating measurement signals from several coating stations measured by gas-type-dependent pressure transducers, it is possible to distinguish global and local causes for a change in the process gas mixture and to constrain the fault locations responsible for this.

Advantageously, at least for the plasma chamber of the coating station, the pressure measuring device connected there uses only a gas-type-dependent pressure transducer. The gas-type-dependent pressure measurement can advantageously be combined with the gas-type-independent pressure measurement known from the prior art discussed above. Based on, for example, two different gases of different thermal conductivity, the process gas composition during the coating of PET bottles with SiOx diffusion barriers can be determined and, if necessary, corrected in the event of measured deviations.

The simultaneous measurement of the pressure as an absolute value by a pressure transducer that is independent of the gas type and as a gas-type-dependent value by a pressure transducer suitable for this purpose enables the stoichiometry of the process gas to be determined in the process gas generator. This enables to detect error patterns that may be caused by mass flow controllers (MFC). In addition, the stoichiometry of the process gas can be determined during ongoing production.

The simultaneous measurement of the pressure as an absolute value and as a gas-type-dependent value also enables to detect the gases that the respective mass flow controller supplies. For example, a leakage at the mass flow controllers can be detected during ongoing production. Finally, the previously required test routine (abliter routine) for the mass flow controllers is eliminated, reducing service times.

Advantageously, the relative deviation (the precursor concentration) between a pressure value measured by the gas-type-independent pressure transducer and a pressure value measured by the gas-type-dependent pressure transducer can be evaluated to control the process gas composition.

In addition, the type of influence of the process can advantageously be determined from a pressure value measured by the gas-type-dependent pressure transducer.

Furthermore, a pressure value measured by the gas type-dependent pressure transducer can advantageously be combined with other measured values of the process characteristics to create diagnoses to accelerate troubleshooting. To ensure reliable coating of the interior of bottles when mixtures of at least two gases are used for the individual process segments of: adhesion promoter, barrier and topcoat (adhesion promoter: O2/HMDSO, barrier: O2/HMDSN, topcoat: Ar/HMDSO), it is important to precisely maintain and monitor the mixing ratios for the respective process. It can happen that mass flow controllers, which are used for gas dosing, set an incorrect gas flow due to a defect. Since there is no quick way to check the coating quality (permeation measurements usually take one to two days), it is essential to detect and correct deviations in the process gas composition that reduce the coating quality directly in the process.

If the pressure p of the process gas supplied to the cylinders is known, the gas composition can be monitored by using a gas-type-dependent Pirani load cell.

The principle will be described in the following: In general, the following applies to the pressure in a pumped volume into which a gas flow f is introduced:

p=a(f)+p_{b}=kf+p_{b} (1)

Here, p_{b} is the base pressure that occurs without gas flow and a(f) is a function that describes the pressure change as a function of the gas flow f. While the pressure-dependent conductance remains the same, which is given in a sufficiently large range around the process pressure, a(f) is a linear function, so that a(f)=k f applies.

Since the total pressure in a system with two gases can be written as the sum of the partial pressures, the following applies to two different gases flowing in at different flows f₁ and f₂:

p=a₁(f₁)+a₂(f₂)+p_{b}=k₁f₁+k₂f₂+p_{b} (2)

By measuring the resulting pressure at different gas flows, the functions a₁(f₁)=k₁ T and a₂(f₂)=k₂ f₂ can be easily determined experimentally. The same applies to the gas-type-dependent pressure measured with the Pirani load cell:

pₚᵢᵣₐₙᵢ=a′₁(f₁)+a′₂(f₂)+p_{b}=k′₁f₁+k′₂f₂+p_{b} (3)

The functions a′₁(f₁) and a′₂(f₂) can also be easily determined experimentally. For the standard flows of the respective process f^{Std}₁ and f^{Std}₂, the pressure values p^{Std}=p(f^{Std}₁, f^{Std}₂) and p^{Std}ₚᵢᵣₐₙᵢ=pₚᵢᵣₐₙᵢ(f^{Std}₁, f^{Std}₂) are known. If a change of one or both fluxes occurs with the new values f*₁ and f*₂, two new pressure values p*=p(f*₁, f*₂) and p*ₚᵢᵣₐₙᵢ=pₚᵢᵣₐₙᵢ(f*₁, f*₂) appear. Then, for the respective differences between standard pressure and new pressure value Δp (difference eq. 2 before/after) and Δpₚᵢᵣₐₙᵢ (difference eq. 3 before/after) applies:

Δp=p*−p^{Std}=k₁f*₁+k₂f*₂+p_{b}−(k₁f^{Std}₁+k₂f^{Std}₂+p_{b})=k₁(f*₁−f^{Std}₁)+k₂(f*₂−f^{Std}₂)=k₁Δf₁+k₂Δf₂

Δpₚᵢᵣₐₙᵢ=p*ₚᵢᵣₐₙᵢ−p^{Std}ₚᵢᵣₐₙᵢ=k′₁(f*₁−f^{Std}₁)+k′₂(f*₂−f^{Std}₂)=k′₁Δf₁+k′₂Δf₂

This results in two equations (Δp=k₁ Δf₁+k₂ Δf₂ and Δpₚᵢᵣₐₙᵢ=k′₁ Δf₁+k′₂ Δf₂) with the two unknowns Δf₁ and Δf₂, which represent the deviation of the two gas flows from the set flow. By rearranging the system of equations and solving for Δf₁ and Δf₂, the deviations of the two process gas flows from the setpoint can then be calculated. In this way, deviations from the setpoint flow can quickly be detected and corrected, so that process reliability is ensured.

The gas-type-independent measurement is preferably carried out by a membrane-based pressure transducer directly after mixing the process gas. The measurement of the gas-type-dependent pressure by a Pirani load cell is advantageously carried out in the coating stations. The gas-type-independent pressure in the coating stations can be calculated using known conductance values of the piping up to the station. It is understood that the features and embodiments explained above and below are disclosed not only in the combinations indicated in each case but are also to be regarded as belonging to the disclosure in their separate position as well as in other combinations.

In the following, the invention is explained in more detail with reference to the drawings with preferred embodiments.

### BRIEF DESCRIPTION OF THE DRAWINGS

FIG. 1 shows a schematic block diagram of a preferred embodiment of a coating station of the device for plasma treatment of containers.

FIG. 2 shows a schematic block diagram of a preferred embodiment of the process gas generator of the device for plasma treatment of containers.

### DETAILED DESCRIPTION

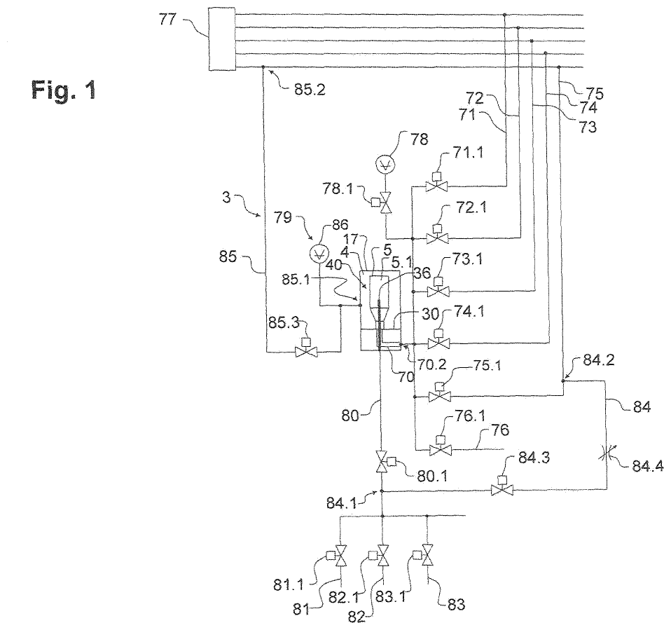

FIG. 1 exemplarily shows a schematic block diagram at a treatment station 40 of a coating station or plasma station 3, which can be arranged once or several times in a plasma chamber 17. In the plasma chamber 17, the container 5 is inserted and positioned in the chamber interior 4 in a gas-tight and/or air-tight manner. In the present case, a chamber base 30 thereby has a vacuum channel 70. The vacuum channel 70 opens with its first side 70.1 into the plasma chamber 17 or, depending on the position of a gas lance 36, also establishes a gas-permeable connection into the container interior 5.1 of the container 5. It can particularly be provided that in a state of the gas lance 36 retracted into the container interior 5.1, the container interior 5.1 is isolated from the chamber interior 4, i.e. sealed, whereas in a lowered state of the gas lance 36, a gas-permeable connection is created between the container interior 5.1 of the container 5 and the chamber interior 4.

Furthermore, at least a first to fifth vacuum line 71 . . . 75 and at least one ventilation line 76 can be connected to a second side 70.2 of the vacuum channel 70, wherein in particular the ventilation line 76 can be connected or disconnected via an adjustable and/or controllable valve device 76.1. In addition, each of the first to fifth vacuum lines 71 . . . 75 can each comprise at least one adjustable and/or controllable valve device 71.1 . . . 75.1, wherein the valve devices 71.1 . . . 76.1 are designed to be controllable via a machine controller of the device for plasma treatment of containers 5, which is not shown in more detail.

At the end facing away from the second side 70.2 of the vacuum channel 70, the first to fifth vacuum lines 71 . . . 75 are preferably in fluid-tight connection with a vacuum device 77 common to all vacuum lines 71 . . . 75. In particular, the vacuum device 77 is configured to generate the vacuum required in the plasma chamber 17 and in the container interior 5.1 during the plasma treatment. Furthermore, the vacuum device 77 is configured to generate different negative pressures at the first to fifth vacuum lines 71 . . . 75, i.e. negative pressure stages for each vacuum line 71 . . . 75. Preferably, the fifth vacuum line 75 has a greater vacuum than the first vacuum line 71, i.e. a lower vacuum level. In particular, the vacuum levels may further be reduced with each vacuum line 71 . . . 75 in such a way that the fifth vacuum line 75 has the lowest vacuum level. Alternatively, however, it is also possible to connect the individual vacuum lines 71 . . . 75 to separate vacuum devices 77.

In particular, the plasma chamber 17 and/or the container interior 5.1 may be lowered to different vacuum levels via the first to fifth vacuum lines 71 . . . 75. For example, the plasma chamber 17 including the container interior 5.1 may be lowered to a first vacuum level via the first vacuum line 71 when the valve device 71.1 is open, while, for example, when the valve device 72.1 of the second vacuum line 72 is open, a lower vacuum level than the first vacuum level is created both in the plasma chamber 17 and in the container interior 5.1. Furthermore, it can also be provided that, for example, the fifth vacuum line 75 is formed as a process vacuum line which is opened synchronously with the supply of a process gas during the plasma treatment to maintain the vacuum. In this way, the provided process vacuum line avoids a transfer of extracted process gas into the supply circuits of the further vacuum lines, for example the first to fourth vacuum lines 71 . . . 74.

Also, a pressure measuring device 78 may be assigned to the first to fifth vacuum lines 71 . . . 75, for example in the form of a pressure measuring tube, which is configured to detect the negative pressure generated via the first to fifth vacuum lines 71 . . . 75. In particular, an upstream valve device 78.1 may be assigned to the pressure measuring device 78 and the pressure measuring device 78 may be arranged in a fluid connection of the second vacuum line 72 to the second side 70.2 of the vacuum channel 70.

In addition, the gas lance 36 can be coupled via an exemplary central process gas line 80 with exemplary first to third process gas lines 81 . . . 83, wherein different process gas compositions may be supplied via the first to third process gas lines, in particular to the container interior 5.1 by the gas lance 36. Each of the first to third process gas lines 81 . . . 83 can furthermore each have at least one valve device 81.1 . . . 83.1 which can be regulated and/or controlled, for example, via the central machine control system of the device for plasma treatment of containers. 83.1. Consequently, the central process gas line 80 can also comprise such a controllable and/or adjustable valve device 80.1.

In addition, preferably, between the valve device 80.1 of the central process gas line 80 and the valve devices 81.1 . . . 83.1 of the first to third process gas line 81 . . . 83, at least one bypass line 84 is branched off in a fluid-tight manner with its first side 84.1, wherein the second side 84.2 of the bypass line also opens in a fluid-tight manner into one of the first to fifth vacuum lines 71 . . . 75. In the event of a malfunction of the coating station 3, the bypass line 84 is configured to divert the process gas flowing in via the first to third process gas lines 81 . . . 83 before it is fed into the plasma chamber 17, advantageously into one of the first to fifth vacuum lines 71 . . . 75. Particularly advantageously, the bypass line 84 opens with its second side 84.2 in a fluid-tight manner into the vacuum line of the central vacuum device 77 with the lowest vacuum level, i.e. according to the exemplary embodiment of FIG. 1, into the fifth vacuum line 75. In an alternative embodiment, the bypass line 84 can also open in a fluid-tight manner into a separate, not shown, vacuum device.

Furthermore, the bypass line 84 comprises at least one valve device 84.3 which can be controlled and/or adjusted via the central machine control of the plasma treatment device, as well as at least one controllable and/or adjustable throttle device 84.4 for flow throttling or limiting the volumetric flow of process gas flowing through the bypass line 84. For example, the throttle device 84.4 may be configured as a controllable and/or adjustable sleeve valve and thus in particular it may be configured for limiting the volumetric flow of process gas flowing through the bypass line 84. In particular, the throttle device 84.4 is provided downstream of the valve device 84.3 in the bypass line 84 in the flow direction indicated by arrows.

Particularly advantageously, the throttle device 84.4 may be dimension and/or adjust the inner pipe cross-section of the bypass line 84 such that the volumetric flow of process gas diverted through the bypass line 84 corresponds approximately to the volumetric flow of process gas supplied via the central process gas line 80 to the corresponding coating station 3 during the application of process gas. In other words, the inner tube cross-section of the bypass line 84 is selected or adjusted by the throttle device 84.4 in such a way that approximately the same vacuum conductance is in the bypass line 84 during the discharge of the process gas as in the central process gas line 80 during the application of process gas for the plasma treatment.

Furthermore, a sixth vacuum line 85 can also be connected directly and in particular fluid-tightly with a first side 85.1 to the plasma chamber 17 or flow into it and interact fluid-tightly with a second side 85.2 via the fifth vacuum line 75 with the interposition of an adjustable and/or controllable valve device 85.3 with the central vacuum device 77. The sixth vacuum line 85 is associated with a pressure measuring device 79 for measuring, in particular, the negative pressure within the plasma chamber 17. The pressure measuring device 79 comprises a gas-type-dependent pressure transducer 86. From the pressure value measured by the gas-type-dependent pressure transducer 86, the process quality in the coating station 3, in particular a change in the process gas mixture, can be determined. Furthermore, the type of process influence can be determined from the pressure value measured by the gas-type-dependent pressure transducer 86. Finally, a pressure value measured by the gas-type-dependent pressure transducer 86 can be combined with further measured values of the process recognition to create diagnoses for accelerating troubleshooting. In the case of several coating stations, global and local causes can be distinguished by evaluating the pressure values of the gas-type-dependent pressure sensors 86 provided there, and faults can be restricted to one location.

A typical treatment process at an exemplary coating station 3 without operational malfunction is explained below using the example of a coating process, wherein the process for plasma treatment of containers 5 takes place at a plasma treatment device having several coating stations 3 with the respective treatment stations 40 on a plasma wheel.

In this process, the respective container 5 is first transported to the plasma wheel using an input wheel and, in a pushed-up state of a sleeve-like chamber wall, the container 5 is inserted into the corresponding coating station 3. After completion of the insertion process, the respective chamber wall at this coating station 3 is lowered into its sealed positioning and initially both the chamber interior 4 and the container interior 5.1 of the container 5 are evacuated simultaneously.

After sufficient evacuation of the chamber interior 4, the corresponding gas lance 36 is moved into the container interior 5.1 of the container 5 and a sealing of the container interior 5.1 with respect to the chamber interior 4 is carried out by displacing the sealing element. It is also possible that the gas lance 36 is already moved into the container 5 synchronously with the beginning evacuation of the chamber interior 4. Subsequently, the pressure in the container interior 5.1 can be lowered even further. Furthermore, the positioning movement of the gas lance 36 can already be at least partially parallel to the positioning of the chamber wall. After a sufficiently low vacuum has been reached, process gas is introduced into the container interior 5.1 of the container 5 at the corresponding coating station 3 and the plasma is ignited with the aid of a microwave generator. In particular, the plasma can be used to deposit both an adhesion promoter on an inner surface of the container 5 and the actual barrier and protective layer of silicon oxides.

After completion of the coating process, i.e. the plasma treatment, the gas lance 36 is removed from the container interior 5.1, i.e. lowered, and at least the container interior 5.1 of the container 5 and, where applicable, the plasma chamber 17 are at least partially ventilated, synchronously or prior to the lowering of the gas lance 36.

If at least one of the coating stations 3 is subject to an operational malfunction, then at the time of the introduction or supply of the process gas to or into the corresponding plasma chamber 17, the process gas of this at least one coating station 3 having the operational malfunction is diverted by the bypass line 84. Consequently, at the at least one further coating station 3 of the device for plasma treatment with no operational disturbance and which, at this time, is in the same process step of the admission by process gas, no additional process gas is lead through over the central process gas supply unit. This is because the portion or quantity of process gas predetermined for the coating station 3 that is in an operational malfunction is diverted via the bypass line 84. Thus, there is no degradation of the quality of the plasma coating at this at least one further operational coating station 3 since the treated containers 5 are impinged with the predetermined quantity of process gas. Since the process gas flowing to the at least one coating station 3 having an operational malfunction is diverted by the bypass line 84, the coating process can be operated or continued at the remaining coating stations 3 provided on the device for plasma treatment or at their treatment stations 40 with a consistently high coating quality. First of all, after the plasma chamber 17 has been closed, for example the first and sixth valve devices 71.1 and 85.3 are opened at at least one intactly operating plasma chamber 17, i.e. that is not subject to any operational malfunction, and thus both the container interior 5.1 and the chamber interior 4 of the plasma chamber 17 are evacuated via the first and sixth vacuum lines 71 and 85, respectively. Preferably, the valve device 80.1 of the central process gas line 80 is closed during the opening. In particular, during the evacuation of the container interior 5.1 as well as the plasma chamber 17, the valve device 76.1 of the venting line 76 is also closed. After closing the first valve device 71.1, for example, the second valve device 72.1 can be opened and thus the container interior 5.1 can be lowered to a lower pressure level via the second vacuum line 72. Also, the container interior 5.1 and/or the plasma chamber 17 can still be lowered to further lower vacuum levels via the third or fourth vacuum line 73, 74, if this is necessary for the coating process. After a sufficiently low pressure level has been reached in the container interior 5.1 and/or the plasma chamber 17, the corresponding valve devices 71.1 . . . 75.1 can be closed. Alternatively, it can also be provided that the fifth valve device 75.1 and the sixth valve device 85.3 in particular remain open during the subsequent treatment steps in order to provide a further sufficiently low pressure level in the container interior 5.1 and the plasma chamber 17.

In this case, one or more of the first to third valve devices 81.1 . . . 83.1 of the first to third process gas lines 81 . . . 83.1 and the valve device 80.1 of the central process gas line 80 can already be opened to the at least one intactly operating plasma chamber 17 at the same time as or prior to a positioning of the gas lance 36 within the container interior 5.1. and a process gas of a predetermined composition and a predetermined gas quantity is supplied in particular to the container interior 5.1 via the gas lance 36.

Furthermore, also at the at least one coating station 3 having an operational malfunction, one or more of the first to third valve devices 81.1 . . . 83.1 of the first to third process gas lines 81 . . . 83 are opened in the predetermined time cycle in relation to the remaining coating stations 3 provided at the device 1 for plasma treatment 1, while the valve device 80.1 of the central process gas line 80 of this one coating station 3 having an operational malfunction is closed, as a result of which it is not possible for the process gas to flow into the corresponding plasma chamber 17. Thus, the at least one coating station 3 having an operational malfunction would be supplied with a process gas quantity corresponding to the process gas quantity predetermined for this coating station 3 in intact operating mode. However, particularly preferably at the time of the opening of one or more of the first to third valve devices 81.1 . . . 83.1 of the first to third process gas lines 81 . . . 83 of the at least one coating station 3 having an operational malfunction, the valve device 84.3 is opened at the same time or shortly beforehand and the process gas is discharged via the bypass line 84.

In particular, in the at least one coating station 3 having an operational malfunction, at the time when the valve device 84.3 of the bypass line 84 is opened, the valve device 80.1 of the central process gas line 80 is closed in such a way that the process gas provided via the central process gas supply unit is supplied to the central vacuum device 77 via the bypass line 84. In particular, the process gas is thereby discharged via the fifth vacuum line 75. In particular, the process gas can be fed to the coating stations 3 or the respective treatment station 40 via a rotary distributor provided in the center of the plasma wheel, whereby the actual process gas distribution can be carried out via ring lines.

After a sufficient supply of process gas, the microwave generator ignites the plasma in the container interior 5.1 of the container 5. In this context, it can be provided that, for example, the valve device 81.1 of the first process gas line 81 closes at a predetermined time, while the valve device 82.1 of the second process gas line 82 is opened to supply a process gas of a second composition. At least temporarily, the fifth valve device 75.1 and/or the sixth valve device 85.3 can also be open to maintain a sufficiently low negative pressure, in particular in the container interior 5.1 and/or the process chamber 17. In this case, a pressure level of approx. 0.3 mbar turns out to be appropriate.

After completion of the plasma treatment, the valve devices 81.1 . . . 83.1 of the first to third process gas line 81 . . . 83 as well as all valve devices 71.1 . . . 75.1, 85.3 of the first to sixth vacuum line 71 . . . 75, 85 that still are open at this time are closed, while the valve device 76.1 of the venting line 76 is opened and at least the container interior 5.1 of the container 5 is at least partially vented after the plasma treatment at the at least one treatment station 40 of the coating station 3. Preferably, the interior 5.1 of the container 5 is vented to atmospheric pressure.

Preferably, the venting occurs via the gas lance 36 in the container interior 5.1. Synchronously to this, the gas lance 36 can be lowered from the container interior 5.1. After sufficient venting of the container interior 5.1 and the plasma chamber 17 to preferably atmospheric pressure, or ambient pressure, the open valve device 76.1 of the venting line 76 is closed. The venting time per container 5 is between 0.1 and 0.4 seconds, preferably about 0.2 seconds. After ambient pressure has been reached within the chamber interior 4, the chamber wall is raised again. The coated container 5 is then removed or transferred to an output wheel.

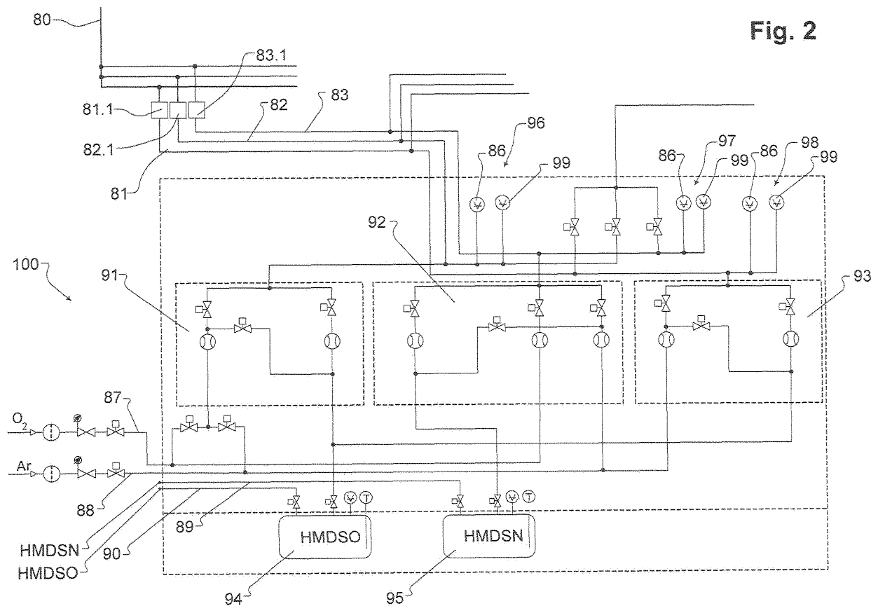

FIG. 2 shows a schematic block diagram of an embodiment of the process gas generator 100 that supplies process gases of different compositions to the coating station 3 of FIG. 1. Oxygen is supplied to the process gas generator 100 via a line 87. Argon is supplied to the process gas generator 100 via a line 88. HMDSN is supplied to the process gas generator 100 via a line 89, and HMDSO is supplied to the process gas generator 100 via a line 90. Valves are arranged in the lines 87 to 90 for dosing or blocking the respective gas supply. The process gas generator 100 comprises three gas mixing units 91, 92 and 93 for providing process gases of different compositions and two gas heating cylinders 94 and 95. The gas heating cylinder 94 is supplied with HMDSO, which is available at the outlet of the cylinder 94 at a temperature and pressure suitable for mixing the gases in the gas mixing units 91 and 93, to which the heated HMDSO is supplied via pipelines equipped with shut-off valves. The gas heating cylinder 95 is supplied with the HDMSN, which is available at the outlet of the cylinder 95 at a temperature and pressure suitable for mixing the gases in the gas mixing unit 92, to which the heated HMDSN is supplied via a pipeline equipped with a shut-off valve.

In addition to the HMDSO, oxygen and argon are supplied to the gas mixing unit 91 via pipelines equipped with shut-off valves. In addition to the HMDSO, argon is supplied to the gas mixing unit 93 via a pipeline. In addition to the HMDSN, oxygen and argon are supplied to the gas mixing unit 92 via pipelines. Gas mixing units 91, 92, and 93 each contain a plurality of mass flow controllers (MFCs) and valves for selectively mixing the gases supplied to them. The gas mixtures are available as process gases at the outlets of the gas mixing units 91, 92 and 93. Specifically, the process gas available at the outlet of gas mixing unit 91 is a gaseous adhesion promoter, the process gas available at the outlet of gas mixing unit 92 is a barrier gas, and the process gas available at the outlet of gas mixing unit 93 is a topcoat gas. The pressure of the respective process gases is measured in the lines 81, 82 and 83 by pressure measuring devices 96, 97 and 98, each of which comprises a gas-type-independent pressure sensor 99 and a gas-type-dependent pressure sensor 86, which, among other things, evaluate the relative deviation (precursor concentration) between the pressure values measured by the two pressure sensors 86, 99 to control the process gas composition.

### LIST OF REFERENCE SIGNS

3 Coating station
4 Chamber interior
5 Container
5.1 Container interior
17 Plasma chamber
30 Chamber base
36 Gas lance
40 Treatment center
70 Vacuum channel
70.1 First side
70.2 Second side
71 First vacuum line
71.1 Valve device
72 Second vacuum line
72.1 Valve device
73 Third vacuum line
73.1 Valve device
74 Fourth vacuum line
74.1 Valve device
75 Fifth vacuum line
75.1 Valve device
76 Venting line
76.1 Valve device
77 Vacuum device
78 Pressure measuring device
78.1 Valve device
79 Pressure measuring device
80 Central process gas line
80.1 Valve device
81 First process gas line
81.1 Valve device
82 Second process gas line
82.2 Valve device
83 Third process gas line
83.1 Valve device
84 Bypass line
84.1 First side
84.2 Second side
84.3 Valve device
84.4 Throttle device
85 Sixth vacuum line
85.1 First side
85.2 Second side
85.3 Valve device
86 Gas-type-dependent pressure transducer
87 Line
88 Line
89 Line
90 Line
91 Gas mixing unit
92 Gas mixing unit
93 Gas mixing unit
94 Gas heating cylinder
95 Gas heating cylinder
96 Pressure measuring device
97 Pressure measuring device
98 Pressure measuring device
99 Gas-type-independent pressure transducer
100 Process gas generator

1.-12. (canceled)

13. A device for plasma treatment of containers (5), comprising:
a process gas generator (100) for generating a process gas mixture; and
at least one coating station (3) which comprises at least one plasma chamber (17) with a treatment station (40),
wherein in the plasma chamber at least one container (5) with a container interior (5.1) can be inserted and positioned at the treatment station (40),
wherein the respective plasma chamber (17) is configured to be at least partially evacuable in order to draw the process gas provided by the process gas generator (100) through the container (5), which provides its interior with an internal coating by plasma treatment,
wherein a gas lance (36) is movable into the interior of the plasma chamber (17),
wherein pressure measuring devices (79, 96-98) are provided at predetermined locations of the device in order to ensure process stability, and
wherein the pressure measuring devices (79, 96-98) comprise gas-type-dependent pressure transducers (86) at least at a part of the predetermined locations of the device.

14. The device of claim 13,
wherein the pressure measuring devices (96-98) measuring pressure in the process gas generator (100) each comprise a gas-type-dependent pressure transducer (86) and a gas-type-independent pressure transducer (99).

15. The device of claim 14,
wherein a relative deviation between a pressure value measured by the gas-type-dependent pressure transducer (86) and a pressure value measured by the gas-type-independent pressure transducer (99) can be evaluated to control a composition of the process gas.

16. The device of claim 13,
wherein at least one pressure measuring device (79) measuring pressure in the plasma chamber (17) of the coating station (3) comprises only a gas-type-dependent pressure transducer (86).

17. The device of claim 13,
wherein the gas-type-dependent pressure transducers (86) are Pirani load cells.

18. The device of claim 17,
wherein by using the Pirani load cells each in combination with the gas-type-independent pressure transducer (99), based on two gases of different thermal conductivity, the gas composition is determinable and is correctable in case of deviation.

19. A method for plasma treatment of containers (5) in a plasma treatment device, comprising the following method steps:
generating a process gas mixture by a process gas generator (100);
inserting and positioning a container (5) with a container interior (5.1) at a treatment station (40) of at least one plasma chamber (17) of a coating station (3);
at least partially evacuating the respective plasma chamber (17) to draw the process gas provided by the process gas generator (100) through the container (5), thereby providing its interior with an internal coating by plasma treatment; and
measuring a pressure at predetermined locations of the plasma treatment device with pressure measuring devices (79, 96-98) to ensure process stability,
wherein the pressure is measured at predetermined locations of the plasma treatment device with pressure measuring devices (79, 96-98) comprising gas-type-dependent pressure transducers (86).

20. The method according to claim 19, further comprising:
determining a change in the process gas mixture in the plasma chamber (17) of the coating station (3) based on a pressure value measured by the gas-type-dependent pressure transducers (86).

21. The method according to claim 19, further comprising:
determining the type of a process influence based on the pressure value measured by the gas-type-dependent pressure transducer (86).

22. The method according to claim 19, further comprising:
concluding a change in the process gas mixture in a respective plasma chamber (17) by evaluating the pressure values measured in the plasma chambers (17).

23. The method according to claim 19,
wherein a pressure value measured by the gas-type-dependent pressure transducer (86) can be combined with further measured values of the process recognition to produce diagnoses for accelerating troubleshooting.

24. (canceled)
